(19) United States
(12) Patent Application Publication
(10) Pub. No.: US 2006/0255412 A1
(43) Pub. Date: Nov. 16, 2006

(54) Enhanced access devices using selective epitaxial silicon over the channel region during the formation of a semiconductor device and systems including same

(76) Inventors: Nirmal Ramaswamy, Boise, ID (US); Eric R. Blomiley, Boise, ID (US)

Correspondence Address: MICRON TECHNOLOGY, INC., 8000 FEDERAL WAY, MAIL STOP 525, BOISE, ID, 83707-0006, US

(21) Appl. No.: 11/129,221

(22) Filed: May 13, 2005

(51) Int. Cl. H01L 29/94

(52) U.S. Cl. 257/368

(57) ABSTRACT

A method used during fabrication of a semiconductor device comprises providing a semiconductor wafer comprising at lease one source region, at least one drain region, and at least one channel region. A mask is formed to cover the source region and the drain region, and which leaves the channel region exposed. A conductive layer is formed which overlies and contacts the channel region, and which does not contact either of the source region and the drain region. The mask is removed and a gate oxide layer is formed on the conductive layer. Processing continues, for example to form transistor control gate on the gate oxide layer over the conductive layer. Another embodiment omits the formation of the conductive layer, and etches the channel region to form a textured surface. A conductive structure is also described.

### FIELD OF THE INVENTION

This invention relates to the field of semiconductor formation and, more particularly, to a method and structure for a semiconductor device transistor having an epitaxial layer formed to contact the transistor channel region.

### BACKGROUND OF THE INVENTION

Transistor structures are required to produce many types of semiconductor devices such as memory devices, logic devices, microprocessors, etc. The electrical properties of the transistors must be strictly controlled to ensure their functionality and the desirability of their electrical operation.

Many aspects of the transistor affect its performance, including the material of manufacture, the doping of the material, and the physical size of each element which makes up the transistor, including the length and width of the channel region. A transistor with a longer and wider channel region will be more reliable and have more predictable operating characteristics than a transistor with a shorter, narrower channel, for example because drive current may be higher with a wider channel. However, forming a larger device is at odds with the semiconductor engineer's ultimate goal of forming smaller devices to increase the density of devices which may be formed in a given area so that costs may be decreased.

A method for forming a transistor having a wider channel without increasing the area used on the semiconductor wafer, and the resulting structure would be desirable.

### SUMMARY OF THE INVENTION

The present invention provides a method which, among other advantages, increases the channel width of a semiconductor device without requiring additional space. In accordance with one embodiment of the invention a conductive layer, for example an epitaxial layer, is formed over a channel region of a semiconductor transistor. The conductive layer may be formed with a number of different processes to have a specified shape, then may be implanted with ions to have a conductivity similar to that of the channel region upon which it is formed. Other transistor features are then formed on or within the semiconductor wafer to form a completed semiconductor device.

The invention may encompass several variations as summarized in the paragraphs below. These descriptions are not intended to be limiting, as there may be variations to each embodiment. For example, a mask may be formed on the source and drain which prevents the formation of the epitaxial layer thereon during its formation on the channel. In a variation, the epitaxial layer may be formed on the source, drain, and channel, then removed from the source and drain by an etch with a mask over the channel.

In a first embodiment (FIGS. 2-5), the epitaxial layer is formed as a rough blanket layer over the channel region. In the FIGS. 2-5 embodiment the source and drain regions are masked off so the epitaxial layer does not form there, but it is contemplated that the epitaxial layer may be formed on, then removed from, the source and drain regions.

In the embodiment of FIGS. 6 and 7, an epitaxial layer is formed on the channel region and a mask is formed over the source, drain, and channel regions. An etch of the epitaxial layer is performed and the mask is removed which results in epitaxial features on the channel as depicted in FIG. 7.

In the FIG. 8 embodiment, the source and drain are masked then an epitaxial feature is formed over the entire channel region. The mask prevents the formation of epitaxial silicon on the source and drain regions.

In the embodiment of FIGS. 9 and 10, a mask is formed over the source and drain, and is patterned on the channel. Epitaxial silicon is grown on the unmasked portion of the channel to result in a structure similar to FIG. 10.

In the embodiment of FIGS. 11 and 12, an epitaxial layer is formed on the channel region, and is then masked and etched. After the mask is removed a structure similar to FIG. 12 remains, resulting in epitaxial features which extend across the length of the channel. In another embodiment, a mask is formed which has openings to expose the channel as depicted in FIG. 13, then the FIG. 13 structure is exposed to an epitaxial silicon-forming ambient. The mask is removed to result in a structure similar to FIG. 14.

In another embodiment, the channel is etched to form openings therein, then gate oxide and other layers are formed over the channel to result in the FIG. 16 structure. The openings effectively increase the channel width.

The completed device provides an electron path which effectively increases the channel width without requiring additional lateral or vertical space. Additional advantages will become apparent to those skilled in the art from the following detailed description read in conjunction with the appended claims and the drawings attached hereto.

### BRIEF DESCRIPTION OF THE DRAWINGS

FIG. 1 is a cross section depicting an exemplary starting structure for use with each embodiment of the present invention;

FIGS. 2-5 are isometric depictions of a first embodiment of the present invention;

FIGS. 6 and 7 are isometric depictions of a second embodiment of the present invention;

FIG. 8 is an isometric depiction of a third embodiment of the present invention;

FIGS. 9 and 10 are isometric depictions of a fourth embodiment of the present invention;

FIGS. 11 and 12 are isometric depictions of a fifth embodiment of the present invention;

FIGS. 13 and 14 are isometric depictions of a sixth embodiment of the invention;

FIG. 15 is an isometric depiction, and

FIG. 16 is a cross section, of a seventh embodiment of the invention;

FIG. 17 is an isometric depiction of various components which may be manufactured using devices formed with an embodiment of the present invention; and

FIG. 18 is a block diagram of an exemplary use of the invention to form part of a memory device having a storage transistor array.

It should be emphasized that the drawings herein may not be to exact scale and are schematic representations. The drawings are not intended to portray the specific parameters, materials, particular uses, or the structural details of the invention, which can be determined by one of skill in the art by examination of the information herein.

### DETAILED DESCRIPTION OF THE ILLUSTRATED EMBODIMENTS

The term “wafer” is to be understood as a semiconductor-based material including silicon, silicon-on-insulator (SOI) or silicon-on-sapphire (SOS) technology, doped and undoped semiconductors, epitaxial layers of silicon supported by a base semiconductor foundation, and other semiconductor structures. Furthermore, when reference is made to a “wafer” in the following description, previous process steps may have been utilized to form regions or junctions in or over the base semiconductor structure or foundation. Additionally, when reference is made to a “substrate assembly” in the following description, the substrate assembly may include a wafer with layers including dielectrics and conductors, and features such as transistors, formed thereover, depending on the particular stage of processing. In addition, the semiconductor need not be silicon-based, but could be based on silicon-germanium, silicon-on-insulator, silicon-on-sapphire, germanium, gallium arsenide, gallium nitride, or silicon carbide, among others. Further, in the discussion and claims herein, the term “on” used with respect to two layers, one “on” the other, means at least some contact between the layers, while “over” means the layers are in close proximity, but possibly with one or more additional intervening layers such that contact is possible but not required. Neither “on” nor “over” implies any directionality as used herein.

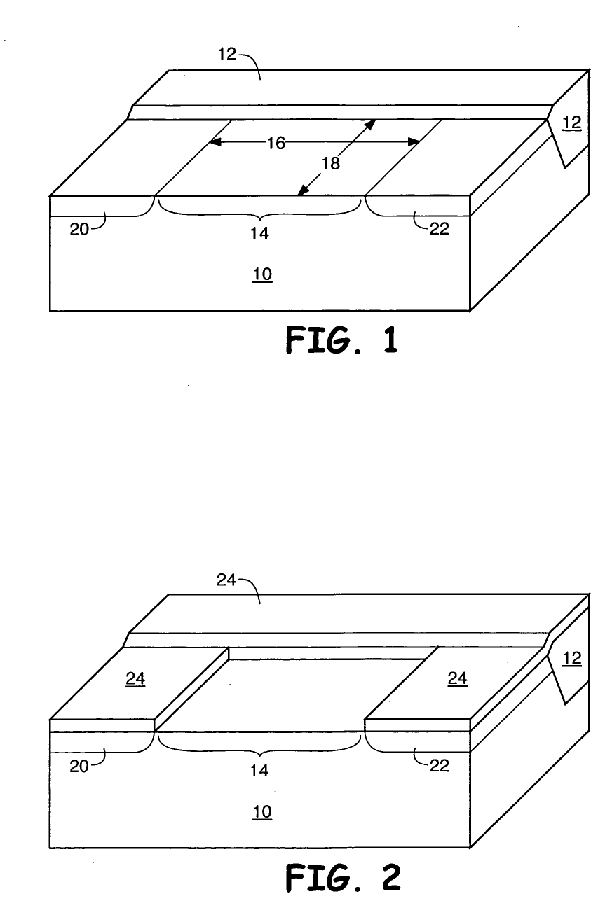

FIG. 1 depicts a cross section of an exemplary starting structure which may be found with each embodiment of the invention described below. FIG. 1 depicts a semiconductor wafer 10 (or a segment of a semiconductor wafer) and a shallow trench isolation (STI, field oxide) region 12 formed therein. FIG. 1 further depicts a transistor channel region 14 having a length 16 and a width 18, a transistor source region 20 and a transistor drain region 22. The source, drain, and channel regions are together conventionally referred to as the “active area.” The transistor source, drain, and channel are typically formed by ion implantation, and at this point in the process they may not yet be implanted but are delineated in FIG. 1 to depict their future location. The channel length of the FIG. 1 structure is defined at one side by the source region 20 and at the other side by the drain region 22. The channel width 18 is defined at one side by a first STI region 12 (depicted at the end of the upper arrowhead of element 18) and by a second STI region (not depicted, but which would begin at the end of the lower arrowhead of element 18).

The channel width 18 is directly proportional to the drive current which can pass through the channel region. A higher drive current is desirable, for example so that when a voltage in excess of the threshold voltage (Vₜ) is applied across the cell, the transistor activates in a minimum amount of time. However, as previously stated, a narrower channel is desirable from space considerations so that a maximum number of devices may be formed in a given area. To increase the effective width, the channel region 14 is texturized to increase the surface area, thereby increasing the width without increasing the size of the device. Various methods to texturize the channel are described below.

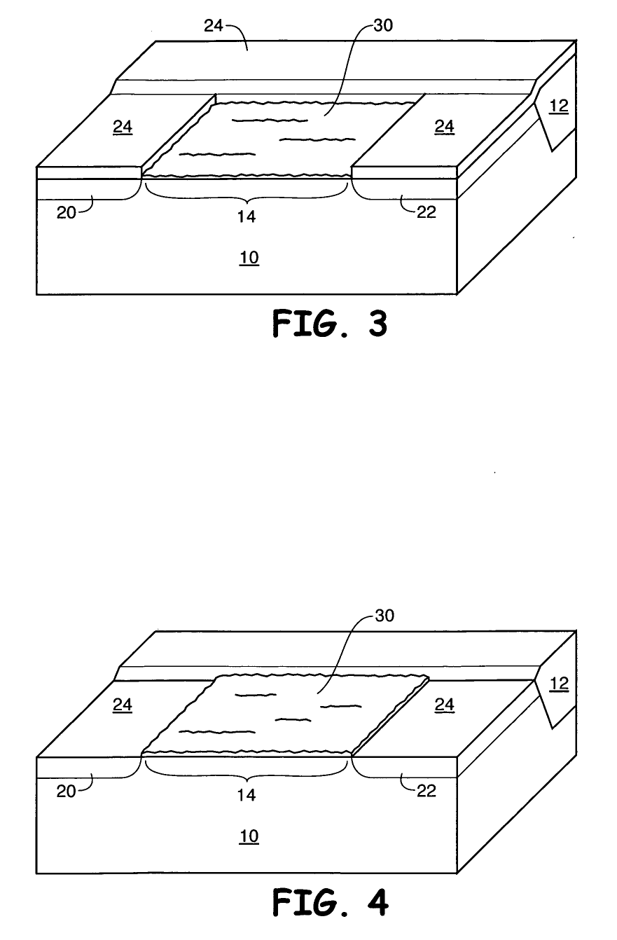

In one embodiment to texturize the channel region 14, a conductive layer such as epitaxial silicon is formed on the channel region 14. A first process for forming a textured channel region is depicted in FIGS. 2-4. FIG. 2 depicts the FIG. 1 structure subsequent to the formation of a patterned masking layer 24, such as a layer of silicon nitride (Si₃N₄) or silicon dioxide (SiO₂) between about 50 Å and about 1,000 Å thick formed using a conventional chemical vapor deposition (CVD) process and patterned using optical lithography. The patterned masking layer 24 is a material which prevents formation of a subsequent epitaxial layer on the source and drain regions, and on other silicon surfaces which may be exposed. As is known in the art, the epitaxial silicon layer is deposited selectively and will only form as a crystal layer on a crystal surface such as a silicon wafer, and thus the silicon nitride mask prevents its formation on other parts of the substrate assembly.

Subsequently, the FIG. 2 structure is exposed in a deposition chamber to an ambient which forms a roughened epitaxial silicon layer 30 on the exposed portions of the silicon wafer 10, specifically the channel region 14 as depicted in FIG. 3. In one embodiment the ambient comprises introducing dichlorosilane (SiH₂Cl₂) and hydrogen chloride (HCl) into the chamber, each gas at a flow rate of between about 0.05 standard liters/minute (SLM) and about 1.0 SLM, along with hydrogen gas (H₂) at a flow rate of between about 1.0 to about 75 SLM. The flow is performed at a temperature of between about 650° C. and about 950° C. for a duration of between about 5 seconds and about 500 seconds. This results in a plurality of pyramidal-shaped silicon crystal features which extend vertically from the surface of the channel region. The density of features 30 of FIG. 3 is much higher than that depicted, and will typically be at a density of between about 1 to about 1,000 features/μm². If the epitaxial layer formation continues for a sufficient duration, the layer may form as a solid epitaxial layer having a rough, crystallized surface. A typical crystalline epitaxial feature will be between about 20 Å and about 500 Å in height.

After forming the epitaxial silicon features 30, the transistor channel 14, including the epitaxial features 30 and the wafer 10 under silicon features 30, may be implanted with p-type or n-type dopants, depending on whether the transistor will be a p-channel (PMOS) transistor or an n-channel (NMOS) transistor. The dopant used, typically boron, arsenic, or phosphorous, will be implanted to appropriate levels. The dopants ensure that the horizontal surface of the wafer and the vertically-oriented epitaxial features function as a single surface to conduct electrons or holes across the channel.

After implanting the channel region mask layer 24 is removed to result in the structure of FIG. 4. Subsequently, a layer of gate oxide 50 is formed as depicted in FIG. 5 and wafer processing continues to form a completed semiconductor device, including forming a transistor control gate 52 over the channel region of the active area in a direction parallel to the width of the channel and implanting the source and drain regions.

The epitaxial silicon crystals increase the surface area of the channel region thereby effectively increasing the width of the channel. Thus a higher drive current may be applied to the transistor, which improves the electrical characteristics during operation of the cell. The epitaxial layer of the present embodiment resides only over the channel region of the transistor. In some instances it is possible that the mask layer 24 may be misaligned to allow some formation of epitaxial silicon on the source or drain regions, however this is believed to have no excessive adverse effect on the electrical operation of the completed cell. Forming some minimal number of features on the source/drain regions will be encompassed by the invention unless stated otherwise for a particular embodiment.

The channel of the FIG. 4 structure requires the same linear (straight line) distance for its width as the FIG. 1 structure, however the effective channel width of the transistor of FIG. 5 is increased due to the roughened topography contributed by the epitaxial silicon features 30. Thus the channel of the transistor of FIG. 5 (and the embodiments described below) has a linear width with a first distance, and an effective width with a second distance, wherein the second distance is greater than the first distance. This increased effective width is provided by topography which extends away from the generally planar surface of the semiconductor wafer section 10, in a direction either toward or away from the control gate 52.

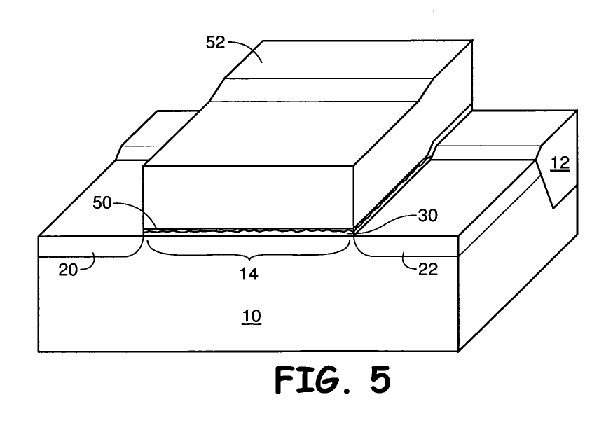

Another method for forming the patterned epitaxial layer using a patterned mask is depicted in FIGS. 6 and 7. In this process an epitaxial layer 60 is formed on channel region of the FIG. 1 structure, and a patterned mask 62 such as silicon nitride, silicon dioxide, or carbon is formed over the epitaxial layer 60 as depicted in FIG. 6. The patterned mask 62 comprises a plurality of circular (round or oval) openings therein, which are spaced so that a wet or dry etch will undercut the mask 62. Subsequent to the etch, the mask 62 is remove to result in a plurality of cone-shaped protrusions or asperities 70 as depicted in FIG. 7. A wet etch which will remove epitaxial silicon includes potassium hydroxide (KOH) or ethylene diamine pyrocatechol (EDP), and a dry etch includes the use of nitrogen trifluoride (NF₃) or tetrafluoromethane (CF₄). After removing the mask 62, the source, drain, and channel regions may be implanted and a gate oxide layer is formed over the channel region including over the protrusions 70 in accordance with the first embodiment. Wafer processing then continues.

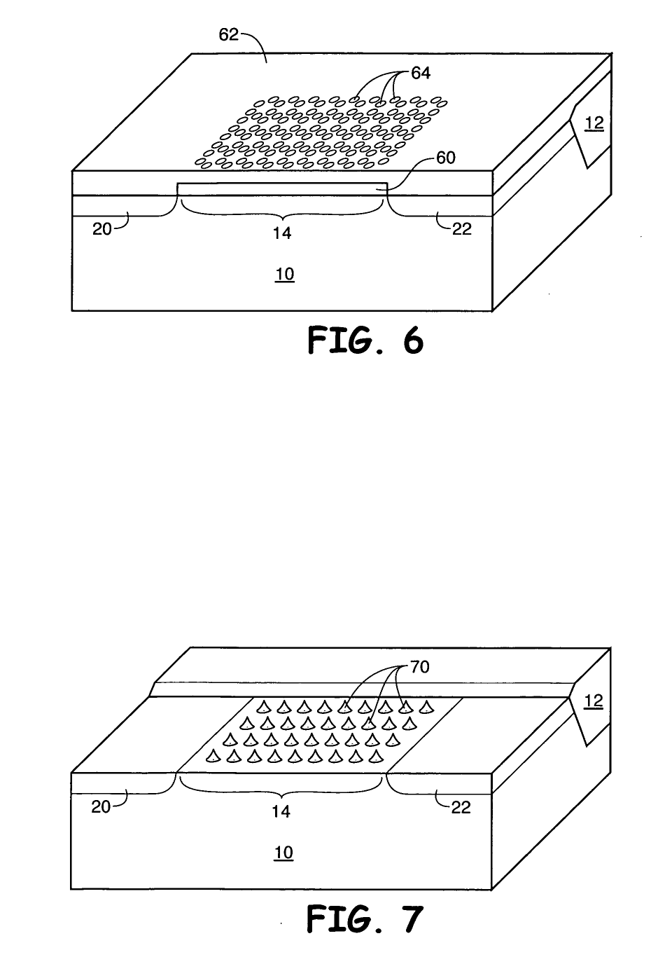

Another embodiment of the invention starts by forming the structure of FIG. 2 wherein at least the source 20 and drain 22 regions of the active area are masked leaving the channel 14 exposed. FIG. 2 depicts all wafer regions masked except the channel 14, including the STI 12. The FIG. 2 structure is then exposed to an environment which forms an epitaxial silicon crystal 80 across the entire channel region as depicted in FIG. 8. This environment may include exposure to SiH₂Cl₂, HCl, and H₂ with the flow rates listed in a previous embodiment to form an epitaxial crystal 80 to between about 20 Å to about 500 Å thick. In this embodiment, the epitaxial layer 80 will function as the entire channel region. When viewed along either the width or length, the epitaxial layer 80 forms a trapezoidal shape due to its crystalline structure. Due to its height and the angles of its four vertically-oriented sides, the epitaxial layer forms, in effect, a device having a wider channel than would be found with a planar channel formed within the wafer itself. The FIG. 8 transistor channel thus comprises only one epitaxial layer feature which contacts the semiconductor wafer and extends away from the semiconductor wafer segment 10.

After forming the FIG. 8 structure, the epitaxial layer 80 may be doped to produce a channel region with a desired conductivity. Dopants and their concentrations for use with conventional channel regions formed within a semiconductor wafer are applicable to the present embodiments.

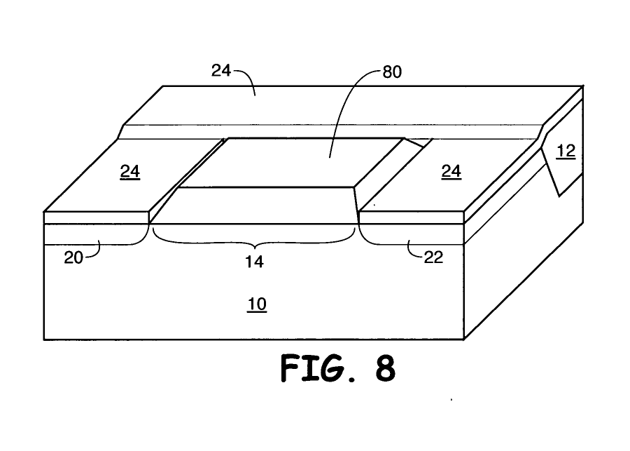

Another embodiment is depicted in FIGS. 9 and 10. As depicted in FIG. 9, a mask 90 is formed over the surface of the wafer substrate assembly which exposes only portions of the channel region 14. The mask prevents formation of the epitaxial layer over silicon regions other than the channel with the pattern depicted. With the present embodiment, the plurality of openings in the mask 90 are each elongated and rectangular to extend across the length of the channel 14. The FIG. 9 assembly is exposed to an environment similar to that described for previous embodiments to result in an epitaxial layer forming on the exposed channel portions. After completing the formation of the epitaxial layer, the mask 90 is removed to result in the structure of FIG. 10, which depicts a plurality of discrete epitaxial layer strips 100, which form to have a triangular cross section due to crystalline formation of the epitaxial layer. These features extend across the length of the channel, and are doped in accordance with previous embodiments. Gate oxide is formed over the channel region, then wafer processing continues according to techniques known in the art.

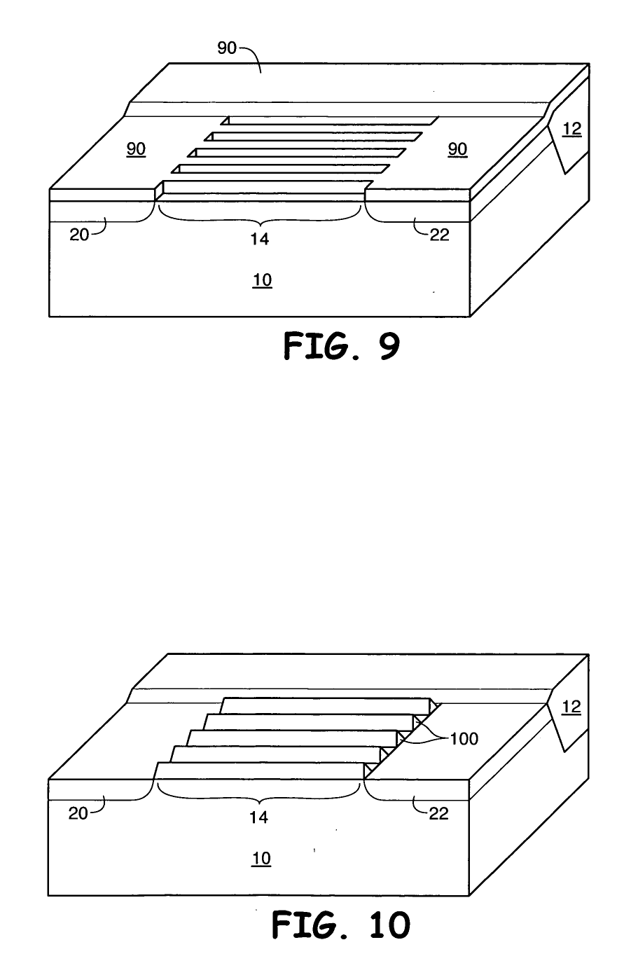

Another method to form a structure similar to that of FIG. 10 using an etch process is depicted in FIGS. 11 and 12. FIG. 11 depicts a first mask layer 24 which is formed to cover all areas of the wafer substrate assembly except for the transistor channel region 14. An epitaxial layer 110 having a uniform thickness is formed across the channel region. Epitaxial layer 110 may be formed by placing the wafer into a deposition chamber and exposing the FIG. 11 structure to an environment such as that previously described comprising flows of SiH₂Cl₂, HCl, and H₂.

After forming the epitaxial layer 110, a second mask layer 112 is formed to have a plurality of elongated strips or slats extending across the channel which define a plurality of openings 114 over the epitaxial layer 110 using a photolithographic process to result in the structure of FIG. 11. The second mask layer 112 may be formed across the entire wafer as depicted, or it may be formed only on epitaxial layer 110 if layer 24 is sufficient to withstand an etch of epitaxial layer 110. The second mask layer 112 exposes the underlying epitaxial layer 110 at the plurality of openings 114 running along the length of the channel region 14.

After forming the FIG. 11 structure, an etch of the epitaxial layer 110 is performed. If a vertical dry etch is performed, for example using CH₂F₂ and at least one of NF₃ or CF₄, the remaining epitaxial features will have a square or rectangular cross section, while an etch with a lateral component, for example NF₃ or CF₄, will result in epitaxial features which have more of a trapezoidal or triangular cross section.

A vertical dry etch which would remove epitaxial silicon includes exposing the FIG. 11 structure to CH₂F₂ at a flow rate of between about 1 sccm and about 100 sccm, or to hydrogen bromide (HBr) at a flow rate of between about 10 sccm to about 1,000 sccm. Another dry etch alternative is chlorine gas (Cl₂) at a flow rate of between about 1 sccm and about 500 sccm. Regardless of the etchant, the etch may be performed at a temperature of between about 50° C. and about 200° C. and at a chamber pressure of between about 1 millitorr and about 100 millitorr for a duration of between about 5 seconds and about 60 seconds.

After exposing the FIG. 11 structure to an etch, the second mask layer 112 and the first mask layer 24 are removed to result in the FIG. 12 structure having epitaxial features 120 comprising a plurality of discrete elongated strips which extend across the length of the channel. This embodiment depicts the results from using an etch having a lateral component, such as NF₃ or CF₄, and resulting features 120 comprising a trapezoidal cross section.

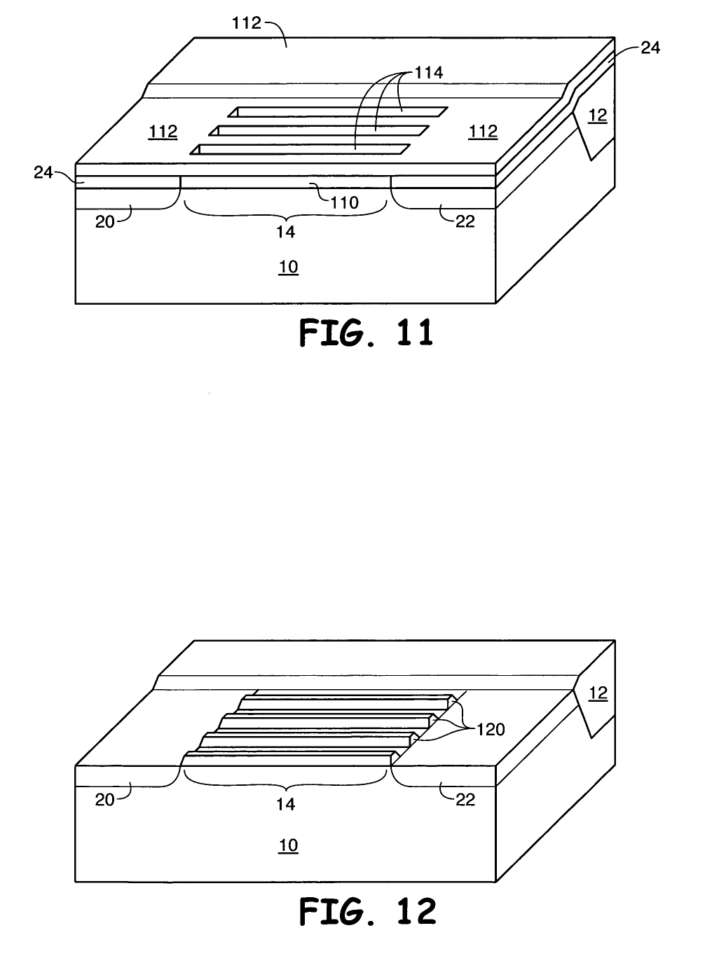

Another embodiment of the invention is depicted in FIGS. 13 and 14, which forms separate epitaxial features using a mask. FIG. 13 depicts a mask layer 130, for example formed using optical lithography, which comprises openings 132 therein to expose the channel region 14 through the openings 132 in the mask 130. In this embodiment, the openings 132 are square or rectangular in shape and it is contemplated that other opening shapes are also possible. The FIG. 13 structure is exposed to an environment which causes a crystalline epitaxial layer to form on the single crystal silicon wafer such as previously described for other embodiments. Subsequently, the mask 130 is removed, which results in the structure of FIG. 14 comprising individual epitaxial features 140 formed on the channel. The features formed are analogous to the shape of the openings 132 in the mask 130, and in the present embodiment will have a square or rectangular base. The epitaxial silicon layer will form as discrete pyramidal shaped asperities due to the crystalline structure of the epitaxial layer. The density of features 140 will be much higher than that depicted, and will typically be at a density of between about 1 to about 1,000 features/μm². A typical crystalline epitaxial feature will be between about 20 Å and about 500 Å in height. After forming the FIG. 14 structure, the channel region comprising features 140 is implanted, a gate oxide is formed over the channel region, then a transistor word line is formed over the channel region in accordance with techniques known in the art.

In contrast with the embodiment of FIGS. 2-5, continuing the epitaxial formation with the embodiment of FIGS. 13 and 14 does not result in the crystals growing together and increasing in density to form a solid layer. Instead, with increasing process duration the features become taller but not more dense.

Another embodiment comprises an etch of the silicon wafer in the channel region and does not comprise the formation of an epitaxial layer. To form this structure, a patterned mask is provided over the wafer surface, for instance the mask 130 of FIG. 13 comprising openings 132 therein. The openings 132 depicted in FIG. 13 may be of any desired shape, for example the shape of the openings of the mask 90 depicted in FIG. 9.

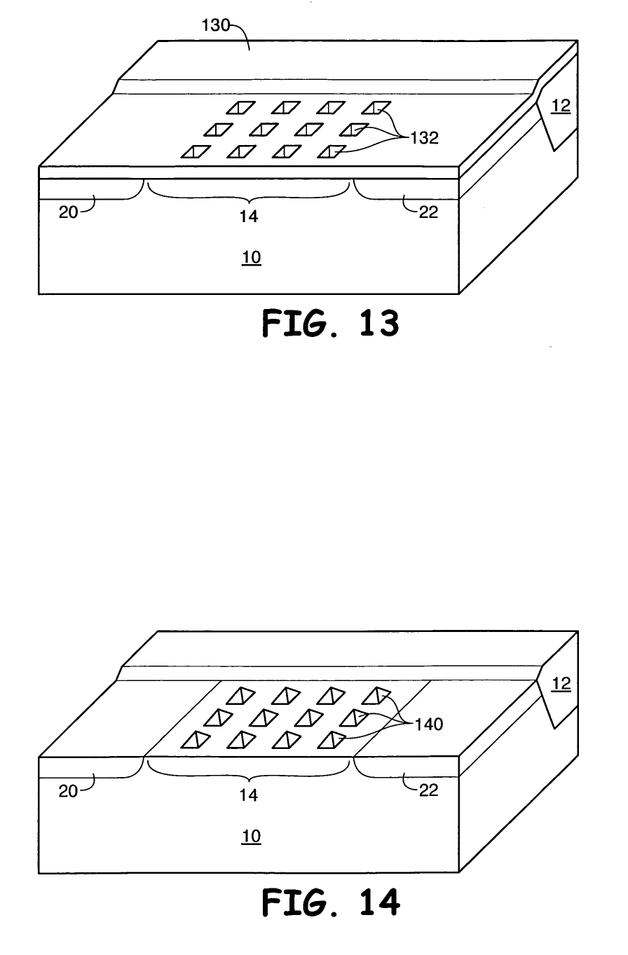

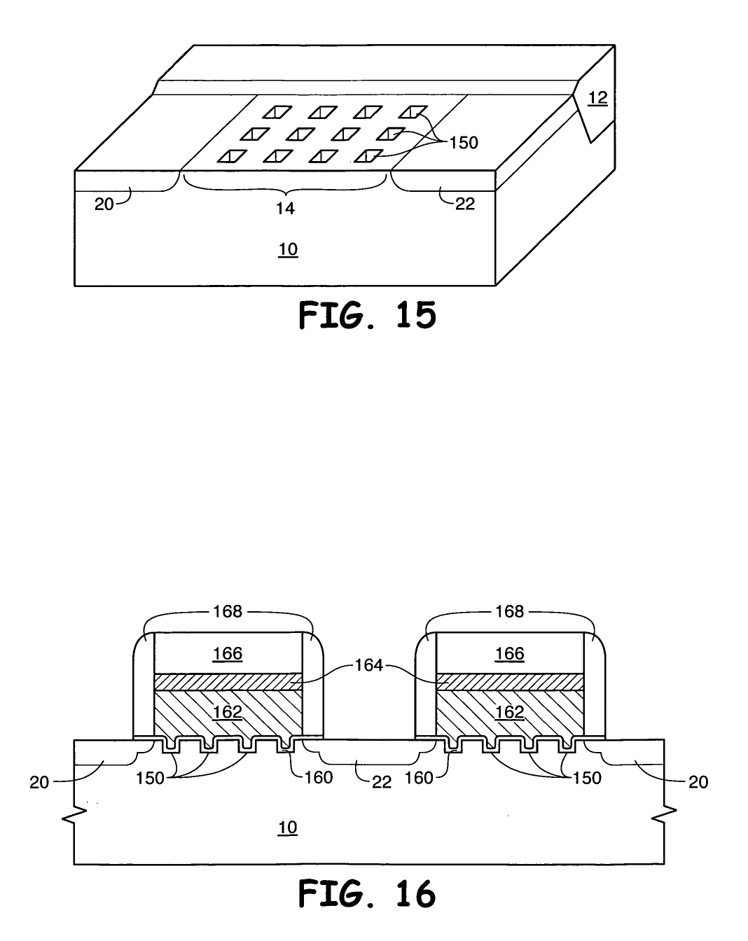

After forming the mask 130, an etch of the channel region is performed and the mask 130 is removed to result in the structure of FIG. 15. The transistor channel region 14 comprises voids 150 therein formed in the wafer 10, and the voids are defined by sidewalls and a bottom formed in the transistor channel region 14 of the wafer 10. One dry etch of the silicon wafer which may be used to form the voids in the wafer comprises the use of CH₂F₂ and at least one of NF₃ and CF₄. After removing the mask the channel region may be doped and wafer processing continues. A cross section of the FIG. 15 structure subsequent to additional processing according to techniques known in the art is depicted in FIG. 16, which depicts voids 150, gate oxide 160, implanted source regions 20 and drain regions 22, polysilicon layer 162, silicide layer 164, dielectric capping layer 166, and dielectric spacers 168. The voids may be formed at a width (in the direction of the width of the channel) of between about 50 Å and about 5,000 Å, a length of between about 50 Å and about 50,000 Å, a depth of between about 50 Å and about 1,000 Å, and at a density of between about 20,000 features/μm² and about 1 feature/μm².

In yet another embodiment, the voids of FIG. 15 may be provided, then an epitaxial feature, for example comprising the epitaxial layer 30 of FIG. 3 or the protrusions 70 of FIG. 7, may be formed on the channel and within the voids to further increase the surface area of the channel region.

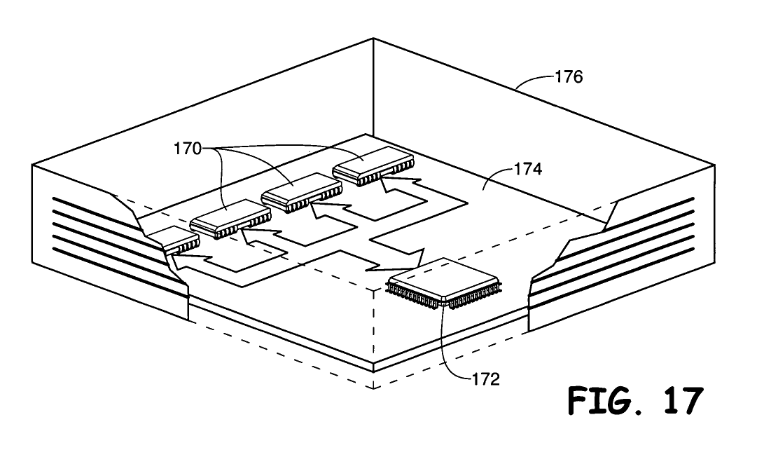

As depicted in FIG. 17, a semiconductor device 170 formed in accordance with the invention may be attached along with other devices such as a microprocessor 172 to a printed circuit board 174, for example to a computer motherboard or as a part of a memory module used in a personal computer, a minicomputer, or a mainframe 176. FIG. 17 may also represent use of device 170 in other electronic devices comprising a housing 176, for example devices comprising a microprocessor 172, related to telecommunications, the automobile industry, semiconductor test and manufacturing equipment, consumer electronics, or virtually any piece of consumer or industrial electronic equipment.

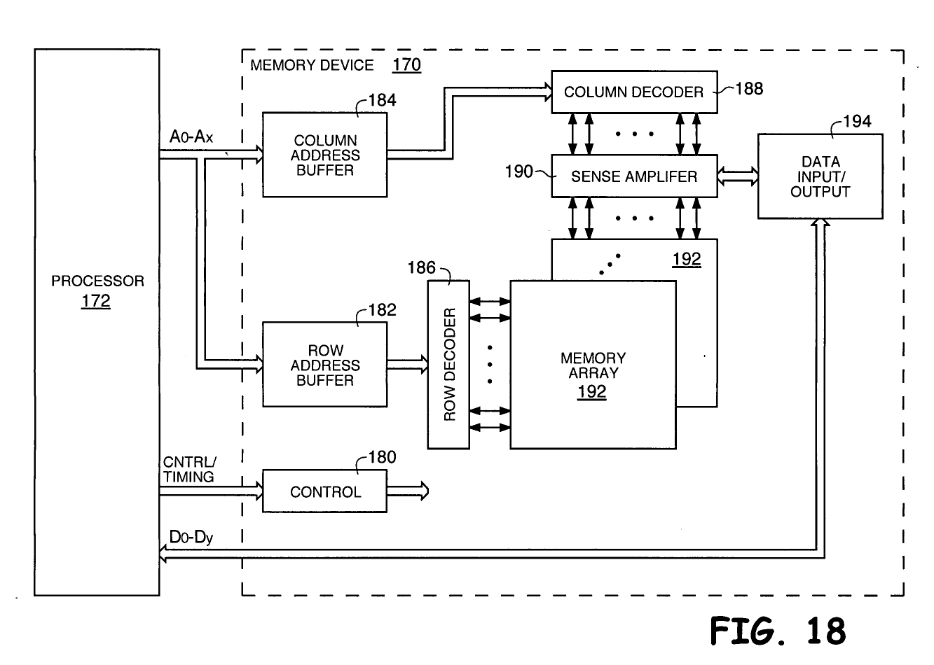

The process and structure described herein can be used to manufacture a number of different structures which comprise a structure formed using a photolithographic process. FIG. 18, for example, is a simplified block diagram of a memory device such as a dynamic random access memory having digit lines and other features which may be formed using an embodiment of the present invention. The general operation of such a device is known to one skilled in the art. FIG. 18 depicts a processor 172 coupled to a memory device 170, and further depicts the following basic sections of a memory integrated circuit: control circuitry 180; row 182 and column 184 address buffers; row 186 and column 188 decoders; sense amplifiers 190; memory array 192; and data input/output 194.

While this invention has been described with reference to illustrative embodiments, this description is not meant to be construed in a limiting sense. Various modifications of the illustrative embodiments, as well as additional embodiments of the invention, will be apparent to persons skilled in the art upon reference to this description. It is therefore contemplated that the appended claims will cover any such modifications or embodiments as fall within the true scope of the invention.

1. A method used during fabrication of a semiconductor device, comprising:
providing a semiconductor wafer substrate assembly comprising a semiconductor wafer, at least one transistor source region, at least one transistor drain region, and at least one transistor channel region;
forming a mask to cover the at least one transistor source region and the at least one transistor drain region, and to leave the at least one transistor channel region exposed;
forming a conductive layer which overlies and contacts the at least one transistor channel region, and which does not contact either of the at least one transistor source region and the at least one transistor drain region;
removing the mask;
forming a gate oxide layer on the conductive layer; and
forming at least one transistor control gate on the gate oxide layer over the conductive layer.

2. The method of claim 1 further comprising:
with the mask covering the at least one transistor source region and the at least one transistor drain region, exposing the transistor channel region to an ambient which is sufficient to form an epitaxial layer on the at least one transistor channel region to provide the conductive layer; and
removing the mask.

3. The method of claim 1 further comprising:
forming the mask layer to cover a first portion of the at least one transistor channel region and to leave at least one second portion of the at least one transistor channel region exposed;
with the mask covering the at least one transistor source region, the at least one transistor drain region, and the first portion of the at least one transistor channel region, forming an epitaxial layer on the second portion of the at least one transistor channel region by exposing the second portion of the at least one transistor channel region to an ambient which is sufficient to form an epitaxial layer on the second portion of the at least one transistor channel region to provide the conductive layer; and
subsequent to forming the epitaxial layer on the second portion of the at least one transistor channel, removing the mask from the at least one transistor source region, the at least one transistor drain region, and the first portion of the at least one transistor channel region.

4. The method of claim 1 further comprising, with the mask covering the at least one transistor source region and the at least one transistor drain region, exposing the at least one transistor channel region to an ambient which forms a roughened epitaxial silicon layer on the at least one transistor channel region.

5. The method of claim 1 further comprising:
placing the semiconductor wafer into a deposition chamber; and
with the mask covering the at least one transistor source region and the at least one transistor drain region, introducing dichlorosilane into the deposition chamber at a flow rate of between about 0.05 standard liters/minute (SLM) and about 1.0 SLM and introducing hydrogen chloride into the deposition chamber at a flow rate of between about 0.05 SLM and about 1.0 SLM to form a roughened epitaxial silicon layer on the at least one transistor channel region.

6. A method used during fabrication of a semiconductor device, comprising:
providing a semiconductor wafer substrate assembly comprising a semiconductor wafer and at least one transistor source region, at least one drain region, and at least one channel region;
forming an epitaxial silicon layer on the at least one transistor channel region and leaving the at least one transistor source and drain regions free from the epitaxial silicon layer;
proving a patterned mask which covers the at least one transistor source and drain regions, and which comprises a plurality of openings therein over the at least one channel region;
etching the epitaxial silicon layer using the patterned mask as a pattern to expose the semiconductor wafer, to pattern the epitaxial silicon layer, and to form epitaxial silicon features on the at least one channel region; and
removing the mask from over the at least one transistor source, drain, and channel regions.

7. The method of claim 6 further comprising implanting the epitaxial silicon features and the at least one channel region subsequent to removing the mask.

8. The method of claim 6 further comprising:
forming a gate oxide layer over the at least one channel region and over the epitaxial silicon features; and
forming at least one transistor control gate over the gate oxide, over the at least one channel region, and over the epitaxial silicon features.

9. The method of claim 6 further comprising:
forming the patterned mask to comprise a plurality of circular openings therein; and
etching the epitaxial silicon layer to form a plurality of cone-shaped protrusions from the epitaxial silicon layer.

10. The method of claim 6 further comprising:
forming the patterned mask to comprise a plurality of elongated strips which extend across the length of the at least one channel region and which define a plurality of openings;
etching the epitaxial silicon layer to from a plurality of elongated strips from the epitaxial silicon layer which extend across the length of the at least one channel region; and
subsequent to removing the mask, forming a gate oxide layer over the at least one channel region and over the epitaxial silicon layer.

11. The method of claim 10 further comprising etching the epitaxial silicon layer with an etch having a lateral component to result in elongated strips having a trapezoidal cross section.

12. A method used in fabrication of a semiconductor device, comprising:
providing a semiconductor wafer substrate assembly comprising a semiconductor wafer, at least one transistor source region, at least one transistor drain region, and at least one transistor channel region;
forming a patterned mask over the at least one transistor source region, the at least one transistor drain region and the at least one transistor channel region, wherein the patterned mask comprises openings therein which expose areas of the at least one transistor channel region;
in the presence of the mask, exposing the semiconductor wafer substrate assembly to an ambient comprising silicon to form an epitaxial silicon layer at the exposed areas of the at least one transistor channel region;
removing the mask;
forming a gate oxide layer over the at least one transistor channel region and over the epitaxial silicon layer; and
forming at least one transistor control gate over the at least one transistor channel region, over the epitaxial silicon layer, and over the gate oxide layer.

13. The method of claim 12 further comprising:
forming the patterned mask to comprise a plurality of square or rectangular openings therein; and
forming the epitaxial silicon layer to comprise a plurality of discrete pyramidal-shaped asperities.

14. The method of claim 13 further comprising forming the pyramidal-shaped asperities at a density of between about 1 feature/μm² to about 1,000 features/μm².

15. The method of claim 13 further comprising forming the pyramidal-shaped asperities to have a height of between about 20 Å and about 500 Å.

16. The method of claim 12 further comprising:
forming the patterned mask to comprise a plurality of elongated rectangular openings therein which extend across a length of the at least one transistor channel region; and
forming the epitaxial silicon layer to comprise a plurality of discrete epitaxial layer strips.

17. The method of claim 12 further comprising forming the discrete epitaxial layer strips comprising a triangular cross section.

18. A method used during fabrication of a semiconductor device, comprising:
providing a semiconductor wafer substrate assembly comprising a semiconductor wafer, at least one transistor source region, at least one transistor drain region, and at least one transistor channel region having a horizontal surface;
forming a patterned mask over the at least one transistor source region, the at least one transistor drain region and the at least one transistor channel region, wherein the patterned mask comprises openings therein which expose areas of the at least one transistor channel region;
etching the horizontal surface of the at least one transistor channel region to form a plurality of voids in the at least one transistor channel region;
forming a gate oxide layer over the horizontal surface of the at least one transistor channel region and within the plurality of voids in the at least one transistor channel region; and
forming at least one transistor control gate within the voids in the at least one transistor channel region and over the horizontal surface of the at least one transistor channel region.

19. The method of claim 18 further comprising doping the at least one transistor channel region which defines the plurality of voids prior to forming the at least one transistor control gate.

20. The method of claim 18 further comprising forming the voids having a width of between about 50 Å and about 5,000 Å, a length of between about 50 Å and about 50,000 Å, a depth of between about 50 Å and about 1,000 Å, and at a density of between about 20,000 features/μm² and about 1 feature/μm².

21.-25. (canceled)

26. A method used during fabrication of an electronic system, comprising:
providing a microprocessor;
providing a semiconductor device fabricated using a method comprising:
providing a semiconductor wafer substrate assembly comprising a semiconductor wafer, at least one transistor source region, at least one transistor drain region, and at least one transistor channel region;
forming a mask to cover the at least one transistor source region and the at least one transistor drain region, and to leave the at least one transistor channel region exposed;
forming a conductive layer which overlies and contacts the at least one transistor channel region, and which does not contact either of the at least one transistor source region and the at least one transistor drain region;
removing the mask;
forming a gate oxide layer on the conductive layer; and
forming at least one transistor control gate on the gate oxide layer over the conductive layer; and
electrically coupling the microprocessor and the semiconductor device.

27. The method of claim 26, wherein the semiconductor device is fabricated using a method further comprising:
with the mask covering the at least one transistor source region and the at least one transistor drain region, exposing the transistor channel region to an ambient which is sufficient to form an epitaxial layer on the at least one transistor channel region to provide the conductive layer; and
removing the mask.

28. The method of claim 26, wherein the semiconductor device is fabricated using a method further comprising:
forming the mask layer to cover a first portion of the at least one transistor channel region and to leave at least one second portion of the at least one transistor channel region exposed;
with the mask covering the at least one transistor source region, the at least one transistor drain region, and the first portion of the at least one transistor channel region, forming an epitaxial layer on the second portion of the at least one transistor channel region by exposing the second portion of the at least one transistor channel region to an ambient which is sufficient to form an epitaxial layer on the second portion of the at least one transistor channel region to provide the conductive layer; and
subsequent to forming the epitaxial layer on the second portion of the at least one transistor channel, removing the mask from the at least one transistor source region, the at least one transistor drain region, and the first portion of the at least one transistor channel region.

29. The method of claim 26, wherein the semiconductor device is fabricated using a method further comprising:
with the mask covering the at least one transistor source region and the at least one transistor drain region, exposing the at least one transistor channel region to an ambient which forms a roughened epitaxial silicon layer on the at least one transistor channel region.

30. The method of claim 26, wherein the semiconductor device is fabricated using a method further comprising:
placing the semiconductor wafer into a deposition chamber; and
with the mask covering the at least one transistor source region and the at least one transistor drain region, introducing dichlorosilane into the deposition chamber at a flow rate of between about 0.05 standard liters/minute (SLM) and about 1.0 SLM and introducing hydrogen chloride into the deposition chamber at a flow rate of between about 0.05 SLM and about 1.0 SLM to form a roughened epitaxial silicon layer on the at least one transistor channel region.
